(19) United States
(12) Patent Application Publication
(10) Pub. No.: US 2011/0103121 A1
(43) Pub. Date: May 5, 2011

(54) STACKED SEMICONDUCTOR DEVICE AND AUTOMATIC CHIP RECOGNITION SELECTION CIRCUIT

(75) Inventor: Toshiaki OSAKABE, Tokyo (JP)

(73) Assignee: ELPIDA MEMORY, INC., Tokyo (JP)

(21) Appl. No.: 12/917,131

(22) Filed: Nov. 1, 2010

(30) Foreign Application Priority Data
Nov. 2, 2009 (JP) 2009-252126

(51) Int. Cl. G11C 5/02; G11C 8/00

(52) U.S. Cl. 365/51; 365/230.08

(57) ABSTRACT

A semiconductor device includes a plurality of stacked chips which are allocated with different self-chip addresses. Each of the plurality of stacked chips includes a frequency change circuit, a self-address storing circuit and a determination circuit. The frequency change circuit changes a first frequency of a signal into a second frequency of the signal. The self-address storing circuit stores a chip select address that is supplied to other chips, in a period of time when the signal as input to the frequency change circuit is different in logic level from the signals as input to the frequency change circuits in the other chips. The determination circuit determines whether the chip select address is identical to the self-chip address.

### BACKGROUND OF THE INVENTION

1. Field of the Invention

The present invention relates to a semiconductor device in which a plurality of semiconductor chips are stacked, and an automatic chip recognition selection circuit.

Priority is claimed on Japanese Patent Application No. 2009-252126, filed Nov. 2, 2009, the content of which is incorporated herein by reference.

2. Description of the Related Art

There have been proposed stacked semiconductor devices having a structure in which a plurality of semiconductor chips are stacked. The stacked semiconductor device is designed for the large-capacity requirements to a semiconductor device such as dynamic random access memories (DRAMs). If the stacked semiconductor devices are used, identifying each of the plurality of chips is necessary to selectively operate any one of the semiconductor chips stacked.

Japanese Unexamined Patent Application Publication No. 2008-77779 discloses a stacked semiconductor device including stacked chips. Each chip includes a self-address storage unit which stores a self-chip address. The self-chip address indicates its own chip address. Each chip further includes a determination unit which compares the self-chip address with a chip select address. The chip select address is commonly supplied to all semiconductor chips. The determination unit determines the identity of the addresses. A specific semiconductor chip is selectively operated by setting a control signal input to a self-semiconductor chip as valid or invalid according to the result of determining whether the addresses are identical.

### SUMMARY

In one embodiment, a semiconductor device may include, but is not limited to, a plurality of stacked chips which are allocated with different self-chip addresses. Each of the plurality of stacked chips may include, but is not limited to, a frequency change circuit, a self-address storing circuit and a determination circuit. The frequency change circuit changes a first frequency of a signal into a second frequency of the signal. The self-address storing circuit stores a chip select address that is supplied to other chips, in a period of time when the signal as input to the frequency change circuit is different in logic level from the signals as input to the frequency change circuits in the other chips. The determination circuit determines whether the chip select address is identical to the self-chip address.

In another embodiment, a semiconductor device may include, but is not limited to, a frequency change circuit, a self-address storing circuit, and a determination circuit. The frequency change circuit changes a first frequency of a signal, which is input, into a second frequency of the signal. The self-address storing circuit stores a chip select address, a mode register setting time period. The determination circuit determines whether the chip select address is identical to a self-chip address that is allocated to a chip, the chip comprising the frequency change circuit, the self-address storing circuit, and the self-address storing circuit.

In still another embodiment, a semiconductor device may include, but is not limited to, a plurality of stacked chips which are allocated with different self-chip addresses. Each of the plurality of stacked chips may include, but is not limited to, a memory cell array, and a peripheral circuit coupled to the memory cell array. The peripheral circuit may include, but is not limited to, a frequency change circuit, a self-address storing circuit, and a determination circuit. The frequency change circuit changes a first frequency of a signal into a second frequency of the signal. The self-address storing circuit stores a chip select address that is supplied to other chips, in a period of time when the signal as input to the frequency change circuit is different in logic level from the signals as input to the frequency change circuits in the other chips. The determination circuit determines whether the chip select address is identical to the self-chip address.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a cross sectional elevation view illustrating a semiconductor device with stacked DRAM chips in accordance with a preferred embodiment of the present invention;

FIG. 2 is a block diagram illustrating configurations of a DRAM on each stacked DRAM chip in the semiconductor device of FIG. 1;

FIG. 3 is a diagram illustrating a circuit configuration of an automatic chip recognition/selection circuit included in the DRAM shown in FIG. 2;

FIG. 4 is a diagram illustrating waveforms that illustrate operations of the automatic chip recognition/selection circuit of FIG. 3;

FIG. 5 is a circuit diagram illustrating a circuit configuration of a latch circuit included in the automatic chip recognition/selection circuit of FIG. 4;

FIG. 6A is a table showing a set of data stored in the latch circuit of FIG. 5;

FIG. 6B is another table showing another set of data stored in the latch circuit of FIG. 5;

FIG. 7 is a circuit diagram illustrating a circuit configuration of a comparator circuit included in the automatic chip recognition/selection circuit of FIG. 4; and

FIG. 8 is a fragmentary cross sectional elevation view illustrating two adjacent DRAM chips stacked one other included in the semiconductor device of FIG. 1.

### DETAILED DESCRIPTION OF THE PREFERRED EMBODIMENTS

Before describing the present invention, the related art will be explained in detail, in order to facilitate the understanding of the present invention.

The semiconductor chip for the stacked semiconductor device disclosed in Japanese Unexamined Patent Application Publication No. 2008-77779 includes a circuit, for example, the self-address storage unit, for storing a self-chip address by a laser-fuse type fuse element or a nonvolatile memory type fuse element. Thus, if the laser-fuse type fuse element is used, there is a problem in which a process of fusing the fuse element and causing an individual semiconductor chip to recognize in advance a self-chip address is necessary before the stacked semiconductor device is manufactured, and hence manufacturing cost is increased.

If the nonvolatile memory type fuse element is used, there is a problem in which a program process of storing a self-chip address is necessary before the stacked semiconductor device is manufactured and hence manufacturing cost is increased.

There is a method of providing an arithmetic circuit which generates an n-bit self-chip address in an individual semiconductor chip to compare a self-chip address with an n-bit chip select address supplied from the outside. For an input/output of the arithmetic circuit in this method, n connection paths for self-chip addresses are provided between stacked semiconductor chips, and different self-chip addresses for all semiconductor chips are generated on the basis of a self-chip address of a chip at the head thereof.

However, like connection paths for the chip select address to be commonly supplied to the chips, the n connection paths for the self-chip address are formed by through electrodes and bump electrodes. Since the number of through electrodes and the number of bump electrodes are increased by n necessary connection paths, there is a problem in which a chip area of a semiconductor chip is increased and hence manufacturing cost is increased. Since the number of through electrodes and the number of bump electrodes are increased as the number of connection paths is increased, there is a problem in which a conduction failure or the like may be easily caused by an assembly failure in a process of manufacturing a stacked semiconductor device, manufacturing yield is decreased, and manufacturing cost is increased.

Embodiments of the invention will be now described herein with reference to illustrative embodiments. Those skilled in the art will recognize that many alternative embodiments can be accomplished using the teaching of the embodiments of the present invention and that the invention is not limited to the embodiments illustrated for explanatory purpose.

In one embodiment, a semiconductor device may include, but is not limited to, a plurality of stacked chips which are allocated with different self-chip addresses. Each of the plurality of stacked chips may include, but is not limited to, a frequency change circuit, a self-address storing circuit and a determination circuit. The frequency change circuit changes a first frequency of a signal into a second frequency of the signal. The self-address storing circuit stores a chip select address that is supplied to other chips, in a period of time when the signal as input to the frequency change circuit is different in logic level from the signals as input to the frequency change circuits in the other chips. The determination circuit determines whether the chip select address is identical to the self-chip address.

In some cases, the second frequency may be two times as high as the first frequency.

In some cases, the signal is a digital signal, and the frequency change circuit may include, but is not limited to, a frequency divider that frequency-divides the signal to generate a frequency-divided signal.

In some cases, the frequency change circuits of the plurality of stacked chips are connected in series and the frequency divider supplies the frequency-divided signal to a next stage frequency divider on the next stage.

In some cases, the chip select address is represented by a combination of n-bits, satisfying 2ⁿ⁻¹<m≦2ⁿ, where m is the number of the stacked chips.

In some cases, each of the plurality of stacked chips further may include, but is not limited to, n of connection path that commonly connects the stacked chips where n is an integer greater than 1, and a single connection path that connects in series the frequency change circuits of the stacked chips.

In some cases, n of the connection path and the single connection path are common in structure to the plurality of stacked chips.

In some cases, the frequency change circuit may include, but is not limited to, a toggle flip-flop.

In some cases, the signal input into the frequency change circuit of the chip on a first stage may be, but is not limited to, an external periodic pulse supplied from outside the semiconductor device.

In some cases, in the period of time the determination circuit in the each chip generates a self-chip select signal that selects the each chip and allows an access to the each chip, when the determination circuit determines that the chip select address is identical to the self-chip address.

In some cases, the period of time may include, but is not limited to, a mode register setting time period.

In some cases, in a normal operation period the determination circuit in the each chip generates a self-chip select signal that selects the each chip and allows an access to the each chip, according to address signals that are supplied from outside the semiconductor device.

In some cases, each of the stacked chips may be, but is not limited to, a DRAM chip.

In some cases, each of the stacked chips may include, but is not limited to, a command decoder, and in the normal operation period the determination circuit in the each chip supplies the self-chip select signal to the command decoder in the each chip.

In another embodiment, a semiconductor device may include, but is not limited to, a frequency change circuit, a self-address storing circuit, and a determination circuit. The frequency change circuit changes a first frequency of a signal, which is input, into a second frequency of the signal. The self-address storing circuit stores a chip select address, a mode register setting time period. The determination circuit determines whether the chip select address is identical to a self-chip address that is allocated to a chip, the chip comprising the frequency change circuit, the self-address storing circuit, and the self-address storing circuit.

In some cases, in the mode register setting time period the determination circuit generates a chip select signal, when the determination circuit determines that the chip select address is identical to the self-chip address.

In some cases, in a normal operation period the determination circuit generates a self-chip select signal, according to address signals that are supplied from outside the semiconductor device.

In some cases, the frequency change circuit, the self-address storing circuit, and the determination circuit are integrated in a DRAM chip stacked with at least one other chip.

In still another embodiment, a semiconductor device may include, but is not limited to, a plurality of stacked chips which are allocated with different self-chip addresses. Each of the plurality of stacked chips may include, but is not limited to, a memory cell array, and a peripheral circuit coupled to the memory cell array. The peripheral circuit may include, but is not limited to, a frequency change circuit, a self-address storing circuit, and a determination circuit. The frequency change circuit changes a first frequency of a signal into a second frequency of the signal. The self-address storing circuit stores a chip select address that is supplied to other chips, in a period of time when the signal as input to the frequency change circuit is different in logic level from the signals as input to the frequency change circuits in the other chips. The determination circuit determines whether the chip select address is identical to the self-chip address.

In some cases, the chip select address is represented by a combination of n-bits, satisfying 2ⁿ⁻¹<m≦2ⁿ, where m is the number of the stacked chips. Each of the plurality of stacked chips further may include, but is not limited to, n of connection path that commonly connects the stacked chips where n is an integer greater than 1, and a single connection path that connects in series the frequency change circuits of the stacked chips.

Preferred embodiments of the present invention will now be described in detail with reference to the accompanying drawings. In this embodiment, an embodiment of a stacked semiconductor device configured by stacking a plurality of DRAM chips will be described as an example of a stacked semiconductor device to which the preferred embodiments of the present invention is applied.

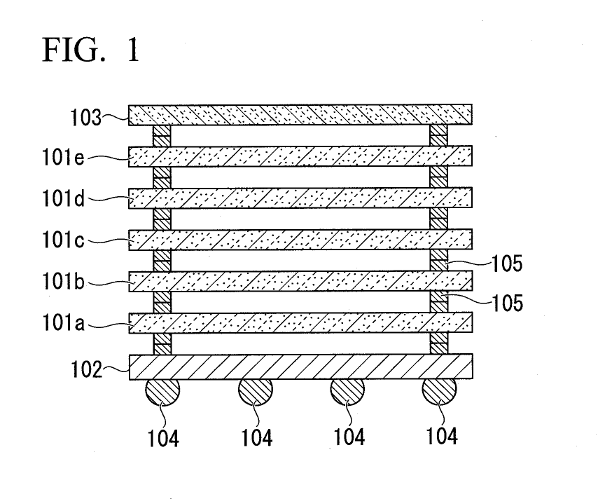

FIG. 1 is a diagram showing an example of a cross-sectional structure of a stacked semiconductor device of this embodiment.

The stacked semiconductor device shown in FIG. 1 includes a lowest-layer interposer substrate 102, a DRAM chip 101a, a DRAM chip 101b, a DRAM chip 101c, a DRAM chip 101d, and a DRAM chip 101e which are stacked in order over the interposer substrate 102, and an interface chip 103 further stacked thereover.

The DRAM chips 101a to 101e forming a five-layered structure can all have the same capacity and the same structure, and can be individually selected to perform a data read operation and a data write operation (access). That is, unique self-chip addresses can be respectively allocated to the DRAM chips 101a to 101e, and a desired DRAM chip can be selectively accessed by commonly supplying a chip select address from the outside. An automatic chip recognition/selection circuit which performs a chip selection operation using a self-chip address is provided in the DRAM chips 101a to 101e, but a specific configuration and operation of the automatic chip recognition/selection circuit will be described later.

On the other surface of an interposer substrate 102, for example, the opposite surface to one surface above which the semiconductor chips are mounted, a plurality of solder balls 104 are provided as external terminals of the stacked semiconductor device. The stacked semiconductor device is electrically connected to the outside, for example, a memory controller, via the solder balls 104, so that an electrical signal can be input/output. The interface chip 103 is a semiconductor chip which controls a signal input/output to/from the DRAM chips 101a to 101e of the five layers.

Bump electrodes 105 are formed on the front and back sides of the DRAM chips 101a to 101e and the back side of the interface chip 103. In the stacked semiconductor device, electrical connection paths are formed in a stack direction by the junction of the inter-chip bump electrodes 105 arranged in cascade, facing toward the stack direction, and pad electrodes and wiring patterns within the chips. In particular, for signals commonly supplied to the DRAM chips 101a to 101e, signal paths serially connected in a longitudinal direction are formed via through electrodes (not shown) and the bump electrodes 105 formed on the DRAM chips.

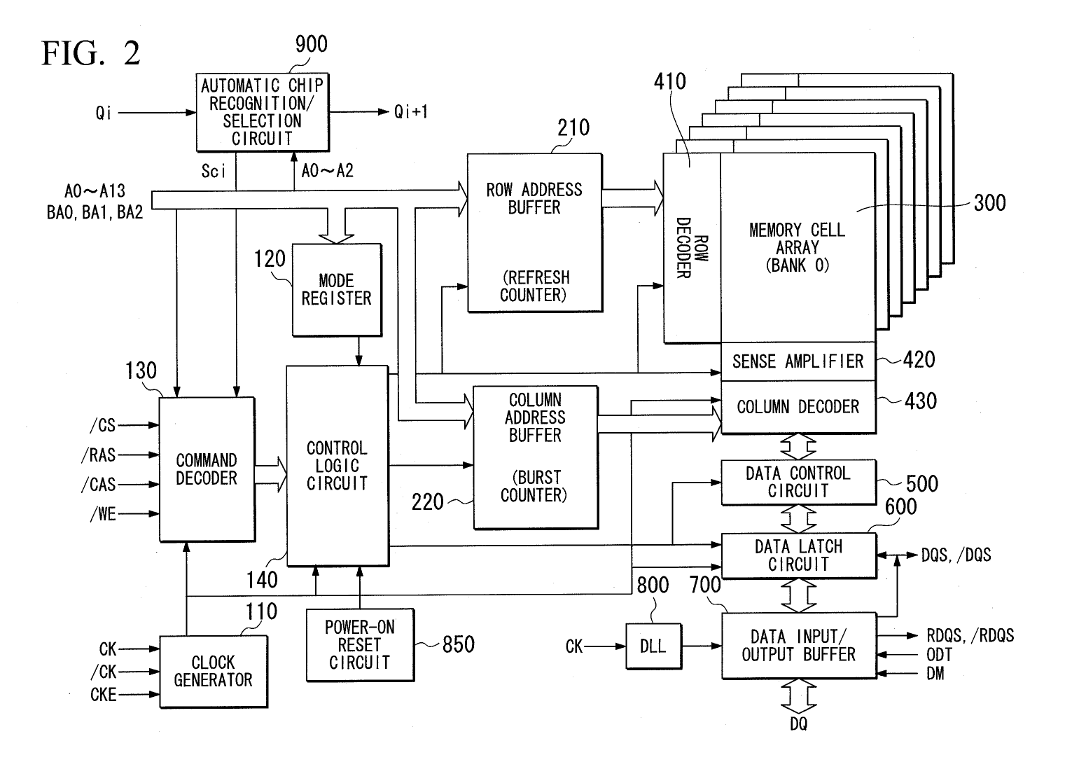

FIG. 2 is a block diagram showing an electrical configuration of the DRAM chips stacked as described above. Since the above-described DRAM chips 101a to 101e all have the same configuration, a DRAM chip 101i is shown in FIG. 2.

The DRAM chip 101i is a chip of a synchronous DRAM as a type of semiconductor memory. In FIG. 2, the DRAM chip 101i may include, but is not limited to, a clock generator 110, a mode register 120, a command decoder 130, a control logic circuit 140, a row address buffer 210, a column address buffer 220, a memory cell array 300, a row decoder 410, a sense amplifier 420, a column decoder 430, a data control circuit 500, a data latch circuit 600, a data input/output buffer 700, a DLL 800, a power-on reset circuit 850, and an automatic chip recognition/selection circuit 900.

Here, the clock generator 110 is a circuit which receives a clock signal CK or /CK and a clock enable signal CKE from the outside and generates an internal clock signal. The internal clock signal is supplied to the command decoder 130, the control logic circuit 140, the column decoder 430, and the data latch circuit 600. The internal clock signal performs the basis for an operation timing of each circuit.

The mode register 120 is a circuit which stores various operation parameters of a burst length, latency, and the like. The operation parameters are generated using address signals A0 to A13 input from the outside in a mode register setting period (hereinafter, referred to as an MRS period) after the semiconductor chips are powered on.

In this embodiment, a self-chip address LA is also stored on the basis of 3 bits of an address signal in the above-described MRS period. This point will be described later.

The command decoder 130 is a circuit for decoding operation commands such as a read command, a write command, and the like. The operation commands are generated using a chip select signal /CS, a row address strobe signal /RAS, a column address strobe signal /CAS, and a write enable signal /WE input from the outside, for example, the memory controller. In this embodiment, when an H-level chip select signal Sci indicating that its own chip is selected is input to the command decoder 130, the command decoder 130 decodes an operation command to command the control logic circuit 140 of the next stage to execute the operation command.

The control logic circuit 140 is a circuit which generates various signals for executing the operation commands decoded by the command decoder 130.

The row address buffer 210 is a circuit which receives the address signals A0 to A13 and bank address signals BA0, BA1, and BA2 input from the outside, and generates row address signals for selecting rows of the memory cell array 300. The row address buffer 210 includes a refresh counter for counting up a row address in a refresh operation.

The column address buffer 220 is a circuit which receives the address signals A0 to A13 and the bank address signals BA0, BA1, and BA2 input from the outside, and generates column address signals for selecting columns of the memory cell array 300. The column address buffer 220 includes a burst counter for counting a burst length.

The memory cell array 300 is configured by arranging memory cells in a matrix shape, wherein a plurality of word lines are laid in a row direction thereof, a plurality of bit lines are laid in a column direction, and the memory cells are arranged at intersections between the word lines and the bit lines. Each memory cell is alternatively selected by selecting a word line and a bit line. The row decoder 410 is a circuit which alternatively selects a word line within the memory cell array 300 on the basis of a row address signal output from the row address buffer 210.

The sense amplifier 420 is a circuit which amplifies a weak data signal from a memory cell appearing on a bit line of the memory cell array 300. The column decoder 430 is a circuit which selects a bit line of the memory cell array 300.

In this example, the memory cell array 300, the row decoder 410, and the sense amplifier 420 are provided in each of a plurality of banks, and each bank is configured to be selected by the bank address signals BA0, BA1, and BA2.

The data control circuit 500 is a circuit which controls an output order of data read from the memory cell array 300 in a burst mode. The data latch circuit 600 is a circuit which temporarily stores input/output data. The data input/output buffer 700 is a circuit which outputs data DQ to an external terminal and receives data DQ from an external terminal.

The DLL circuit 800 is a circuit which generates an internal clock signal defining an operation timing of the data input/output buffer 700 by delaying an external clock signal CK or /CK.

The power-on reset circuit 850 is a circuit which causes the control logic circuit 140 to perform an initialization operation by detecting power supply to the DRAM chip 101. In this embodiment, the power-on reset circuit 850 generates a power-on reset signal having a voltage level (H level) which is the same as a power supply voltage in association with a rising edge of the power supply voltage and having a voltage level (L level) which is the same as a ground voltage after a predetermined time decided according to design has elapsed.

In the MRS period, the automatic chip recognition/selection circuit 900 receives a pulse signal Qi from a low-layer DRAM chip 101, and outputs a pulse signal Qi+1 to an upper-layer DRAM chip 101. In a general operation after the MRS period has expired, the automatic chip recognition/selection circuit 900 outputs the H-level self-chip select signal Sci indicating that its own chip is selected to the command decoder 130 on the basis of the address signals A0 to A2 input from the outside.

Address signals input from the outside to the automatic chip recognition/selection circuit 900 are the address signals A0 to A2 in the drawings, but are not limited to specific addresses and may be other addresses. The following configuration and operation of the automatic chip recognition/selection circuit 900 in which the automatic chip recognition/selection circuit 900 provided in the DRAM chip 101i is an automatic chip recognition/selection circuit 900i and address signals to be commonly input to the automatic chip recognition/selection circuit 900i are a chip select address CA (address signals B0, B1, and B2) will be described.

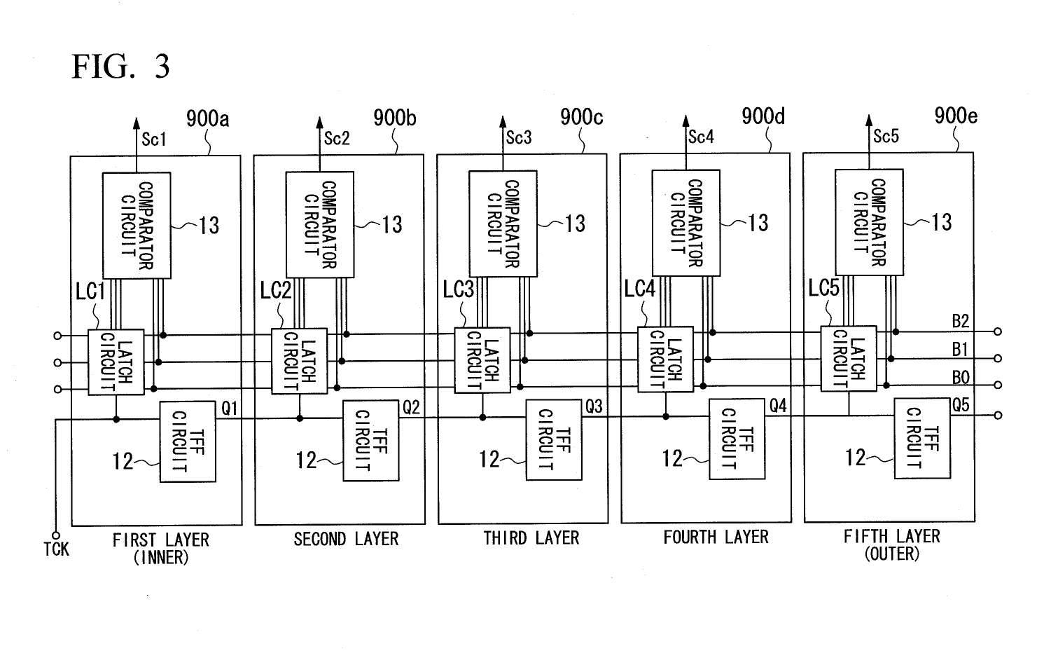

FIG. 3 is a block diagram showing the configurations of automatic chip recognition/selection circuits 900a to 900e provided in the DRAM chips 101a to 101e in the stacked semiconductor device of this embodiment.

FIG. 3 shows the configuration in which the five automatic chip recognition/selection circuits 900a to 900e are connected in cascade as the DRAM chips 101a to 101e of FIG. 1 are stacked in five layers. Since the five automatic chip recognition/selection circuits 900a to 900e have the same configuration, the automatic chip recognition/selection circuit 900a of the five automatic recognition/selection circuits will be described.

The automatic chip recognition/selection circuit 900a includes a frequency change circuit 12, a latch circuit LC1, and a comparator circuit 13. The frequency change circuit 12 is a circuit which receives a reference pulse signal TCK (assumed as a pulse signal Q0), changes a cycle of the pulse signal to twice the cycle, and outputs the pulse signal Q1 to the second-layer automatic chip recognition/selection circuit 900b.

On the basis of the pulse signal Q0 and the chip select address CA input from the outside, the latch circuit LC1 is a circuit which stores a self-chip address LA to be assigned to the mounted DRAM chip 101a.

The comparator circuit 13 is a circuit which compares the self-chip address LA stored by the latch circuit with the chip select address CA input from the outside and outputs a chip select signal Sc1 having the H level if the addresses LA and CA are identical.

FIG. 3 shows the case where both the self-chip address LA and the chip select address CA (the address signals B0, B1, and B2) are expressed by combinations of 3 bits.

Here, the frequency change circuit 12 of the automatic chip recognition/selection circuit 900a includes a well-known toggle flip-flop (hereinafter, referred to as a TFF circuit). The TFF circuit is a flip-flop which inverts an output every time one pulse is input. A plurality of TFF circuits are connected in series.

When a periodic pulse (having a basic cycle T) is input to a first-stage TFF circuit, a cycle of an output pulse signal of a second-stage TFF circuit becomes 2T, a cycle of an output pulse signal of a third-stage TFF circuit becomes 4T, and a cycle is sequentially extended by a multiple hereinafter.

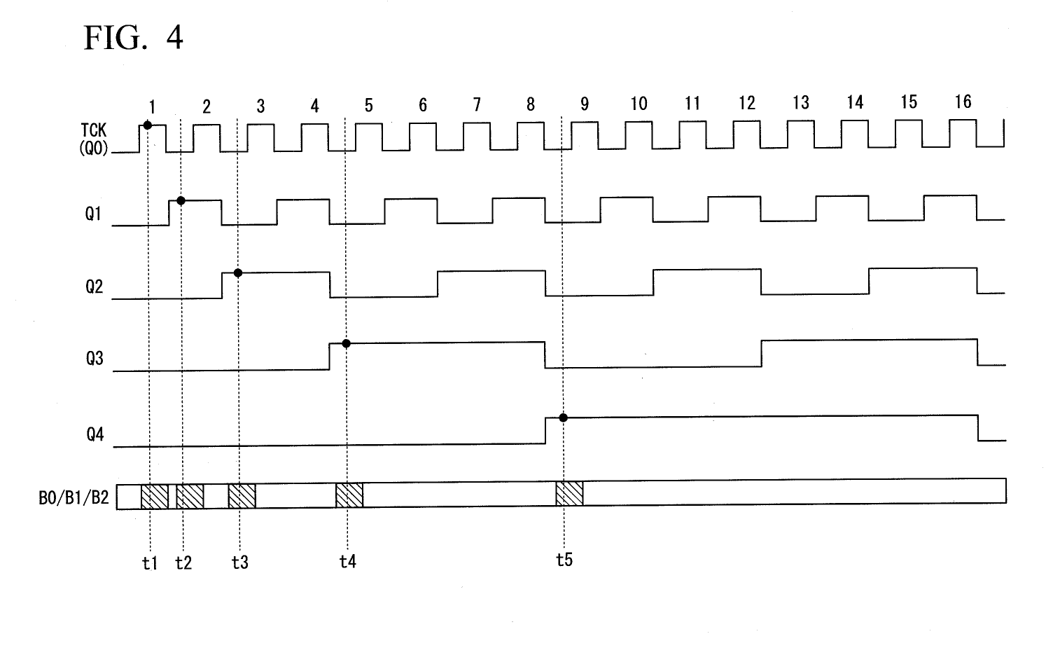

FIG. 4 is a timing chart illustrating the operation of a selection circuit, and shows the variations of logic levels of pulse signals input to the latch circuits of the automatic chip recognition/selection circuits 900a to 900e shown in FIG. 3. The periodic reference pulse signal TCK (the pulse signal Q0) is input from the outside to the frequency change circuit 12 and the latch circuit LC1 of the automatic chip recognition/selection circuit 900a as described above. In FIG. 4, Nos. 1 to 16 are sequentially distributed to the pulse signal Q0.

When m is an integer equal to or greater than 1 and equal to or less than 8, the frequency change circuit 12 of the automatic chip recognition/selection circuit 900a generates a pulse signal Q1 having the H level in synchronization with a (2m−1)^{th} falling edge of the pulse signal Q0 and having the L level in synchronization with a 2m^{th} falling edge of the pulse signal Q0.

When n is an integer equal to or greater than 1 and equal to or less than 4, the frequency change circuit 12 of the automatic chip recognition/selection circuit 900b generates a pulse signal Q2 having the H level in synchronization with a (2n−1)^{th} falling edge of the pulse signal Q1 and having the L level in synchronization with a 2n^{th} falling edge of the pulse signal Q1.

When p is an integer equal to or greater than 1 and equal to or less than 2, the frequency change circuit 12 of the automatic chip recognition/selection circuit 900c generates a pulse signal Q3 having the H level in synchronization with a (2p−1)^{th} falling edge of the pulse signal Q2 and having the L level in synchronization with a 2p^{th} falling edge of the pulse signal Q2.

When q is 1, the frequency change circuit 12 of the automatic chip recognition/selection circuit 900d generates a pulse signal Q4 having the H level in synchronization with a (2q−1)^{th} falling edge of the pulse signal Q3 and having the L level in synchronization with a 2q^{th} falling edge of the pulse signal Q3.

The automatic chip recognition/selection circuit 900i of the DRAM chip 101i of FIG. 2 outputs a pulse signal Qi+1 having the H level in synchronization with a falling edge of the pulse signal Qi output by a low-layer DRAM chip 101 and having the L level in synchronization with the next falling edge of the pulse signal Qi.

In FIG. 4, B0/B1/B2 denotes a chip select address CA, and a period indicated by a diagonal line is a period in which the logic level of one pulse signal of the pulse signals Q0 to Q4 becomes 1 (H level) and the logic levels of the remaining 4 pulse signals become 0 (L level). Here, any period is a time half of a cycle T of the reference pulse signal TCK. A time present in the period, for example, a central time of the period, is sequentially indicated by t1, t2, t3, t4, and t5. In terms of these times, as described above, only the pulse signal Q0 becomes 1 at time t1, only the pulse signal Q1 becomes 1 at time t2, only the pulse signal Q2 becomes 1 at time t3, only the pulse signal Q3 becomes 1 at time t4, and only the pulse signal Q4 becomes 1 at time t5.

At times t1 to t5, a chip select address CA from the outside are input to the latch circuits LC1 to LC5 described below.

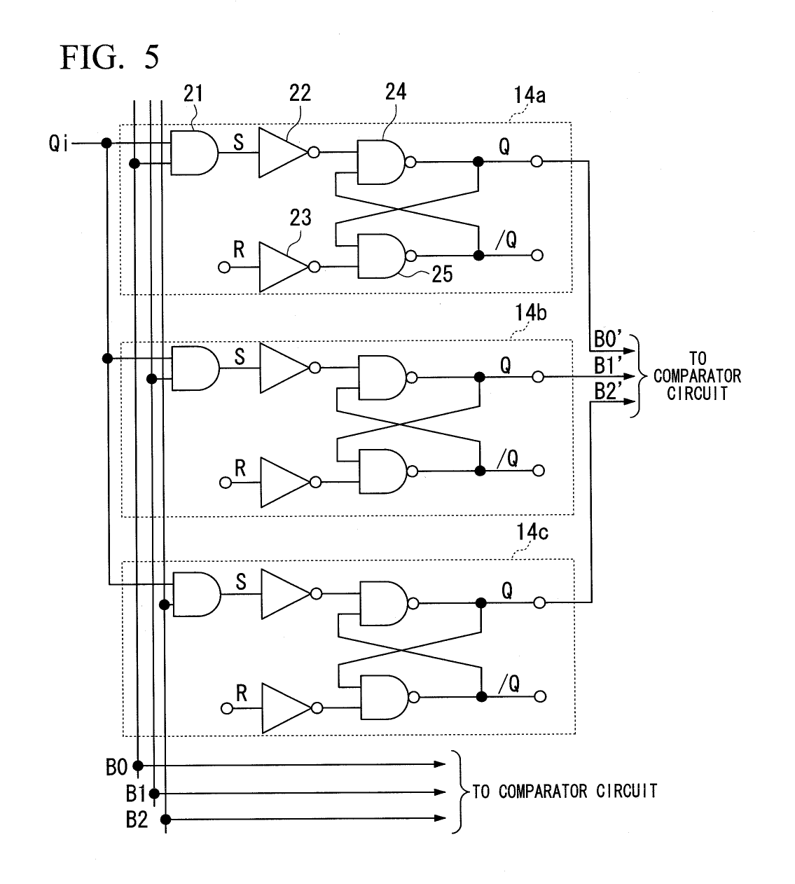

FIG. 5 is a diagram showing an example of a circuit configuration of a latch circuit LCi of the automatic chip recognition selection circuit 900i. The latch circuit LCi is a circuit which latches the chip select address CA when the pulse signal Qi has the H level (corresponding to times t1 to t5 of FIG. 4). The latch circuit LCi includes a sub-latch circuit 14a, a sub-latch circuit 14b, and a sub-latch circuit 14c having the same configuration. The sub-latch circuit 14a latches an address signal B0 of the input chip select address CA, the sub-latch circuit 14b latches an address signal B1 of the input chip select address CA, and the sub-latch circuit 14c latches an address signal B2 of the input chip select address CA.

The sub-latch circuits 14a to 14c include an AND circuit 21, an inverter circuit 22, an inverter circuit 23, a NAND circuit 24, and a NAND circuit 25. The inverter circuit 22, the inverter circuit 23, the NAND circuit 24, and the NAND circuit 25 include an SR flip-flop (hereinafter, referred to as SRFF). A set input terminal S of the SRFF is an input terminal of the inverter circuit 22 to which an output signal of the AND circuit 21 is input. A reset input terminal R of the SRFF is an input terminal of the inverter circuit 23, for example, to which the power-on reset signal of FIG. 2 is input.

The operation of the sub-latch circuit using the sub-latch circuit 14a will be described. First, the inverter circuit 23 outputs the L level by the power-on reset signal changing from the L level to the H level when the power is turned on. The NAND circuit 25 resets a /Q terminal to the H level by the input power-on reset signal. At this time, the pulse signal Qi is not yet input and the AND circuit 21 causes a voltage level of the set input terminal S to be the L level. Accordingly, an output level of the inverter circuit 22 is the H level. Since both voltage levels of two input terminals are the H level, the NAND circuit 24 resets a Q terminal to the L level.

If the pulse signal Qi has the H level in a period when the address signal B0 of the chip select address CA has the H level, the AND circuit 21 outputs the H level. The inverter circuit 22 outputs the L level, and the NAND circuit 24 sets the Q terminal to the H level. At this time, since the power-on signal has the L level, the inverter circuit 23 outputs the H level. Since both the voltage levels of the two input terminals have the H level, the NAND circuit 25 sets the /Q terminal to the L level. Thus, the Q terminal is maintained (latched) at the H level since the input terminal connected to the /Q terminal of the two input terminals of the NAND circuit 24 has the L level even when the pulse signal Qi has the H level thereafter.

If the pulse signal Qi has the H level in a period when the address signal B0 of the chip select address CA has the L level, the voltage level of the Q terminal is maintained as the L level since a state of the reset time is maintained. In the general operation after the MRS period, that is, after the self-chip address LA is latched, the reference pulse signal TCK is not input and is maintained at the L level. Otherwise, if the H level is input to the chip select address when the pulse signal Qi has the H level, the Q terminal has the H level and programming is performed once again.

The above is the operation of the sub-latch circuit 14a. Also, since the sub-latch circuit 14b and the sub-latch circuit 14c only receive the address signal B1 and the address signal B2 respectively input as address signals and have the same configuration as the sub-latch circuit 14a, the sub-latch circuit 14b and the sub-latch circuit 14c perform the same operation as the sub-latch circuit 14a.

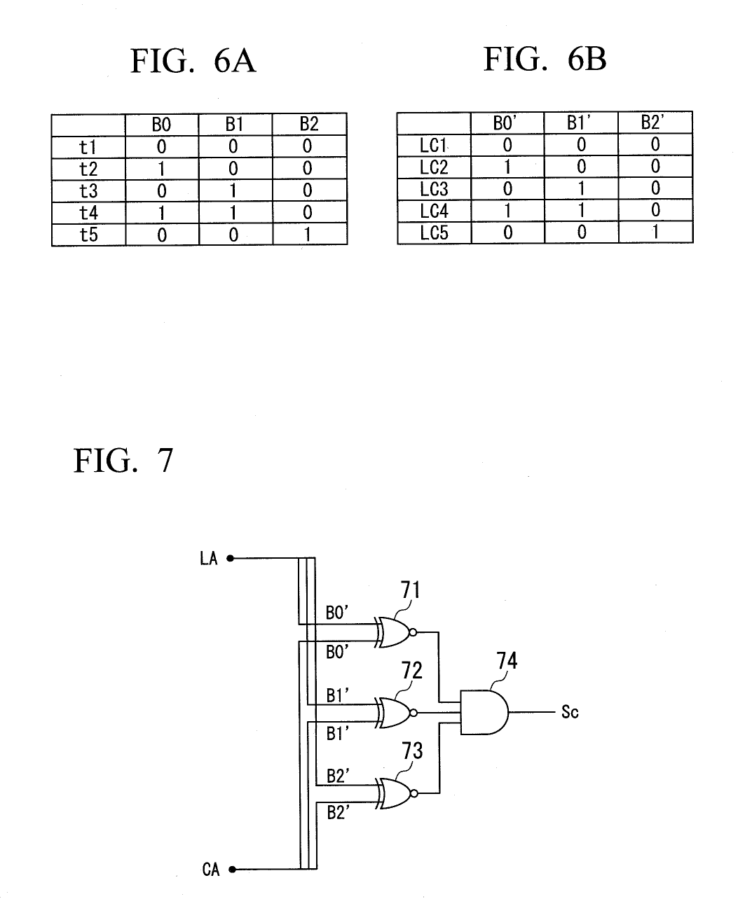

FIGS. 6A and 6B are diagrams illustrating data stored in the latch circuit. At times t1 to t5 shown in FIG. 3, the logic levels of the chip select addresses CA (address signals B0, B1, and B2) input to the latch circuits LC1 to LC5 and the logic levels of self-chip addresses LA (address signals B0′, B1′, and B2′) stored in the latch circuits are shown.

By configuring the latch circuits as shown in FIG. 5, the chip select addresses CA (the address signals B0, B1, and B2) are supplied to the latch circuits when the input pulse signal Qi has the H level, and the self-chip addresses LA (the address signals B0′, B1′, and B2′) are latched (maintained). The logic levels of the chip select addresses CA are expressed by (0/1, 0/1, 0/1) using the logic levels of the address signals B0, B1, and B2, and the logic levels of the self-chip addresses LA are expressed by (0/1, 0/1, 0/1) using the logic levels of the address signals B0′, B1′, and B2′.

In the MRS period after the power is turned on, the reference pulse signal TCK (pulse signal Q0) as a periodic pulse (having a basic cycle T) is input to the automatic chip recognition/selection circuit 900a.

At time t1 shown in FIG. 4, only the pulse signal Q0 has the H level and the other pulse signals have the L level. At time t1, a chip select address CA=(0, 0, 0) is commonly input to the automatic chip recognition/selection circuits 900a to 900e. A self-chip address LA (0, 0, 0) is latched in the latch circuit LC1 of the automatic chip recognition/selection circuit 900a.

The frequency change circuit 12 of the automatic chip recognition/selection circuit 900a sets the pulse signal Q1 to the H level in synchronization with a falling edge of a first pulse of the pulse signal Q0.

At time t2 shown in FIG. 4, only the pulse signal Q1 has the H level and the other pulse signals have the L level. At time t2, a chip select address CA=(1, 0, 0) is commonly input to the automatic chip recognition/selection circuits 900a to 900e. A self-chip address LA (1, 0, 0) is latched in the latch circuit LC2 of the automatic chip recognition/selection circuit 900b.

The frequency change circuit 12 of the automatic chip recognition/selection circuit 900b sets the pulse signal Q2 to the H level in synchronization with a falling edge of a first pulse of the pulse signal Q1.

At time t3 shown in FIG. 4, only the pulse signal Q2 has the H level and the other pulse signals have the L level. At time t3, a chip select address CA=(0, 1, 0) is commonly input to the automatic chip recognition/selection circuits 900a to 900e. A self-chip address LA (0, 1, 0) is latched in the latch circuit LC3 of the automatic chip recognition/selection circuit 900c.

The frequency change circuit 12 of the automatic chip recognition/selection circuit 900c sets the pulse signal Q3 to the H level in synchronization with a falling edge of a first pulse of the pulse signal Q2.

At time t4 shown in FIG. 4, only the pulse signal Q3 has the H level and the other pulse signals have the L level. At time t4, a chip select address CA=(1, 1, 0) is commonly input to the automatic chip recognition/selection circuits 900a to 900e. A self-chip address LA (1, 1, 0) is latched in the latch circuit LC4 of the automatic chip recognition/selection circuit 900d.

The frequency change circuit 12 of the automatic chip recognition/selection circuit 900d sets the pulse signal Q4 to the H level in synchronization with a falling edge of a first pulse of the pulse signal Q3.

At time t5 shown in FIG. 4, only the pulse signal Q4 has the H level and the other pulse signals have the L level. At time t5, a chip select address CA=(0, 0, 1) is commonly input to the automatic chip recognition/selection circuits 900a to 900e. A self-chip address LA (0, 0, 1) is latched in the latch circuit LC5 of the automatic chip recognition/selection circuit 900e.

As described above, the reference pulse signal TCK is supplied to the automatic chip recognition/selection circuit 900a of the lowest-layer DRAM chip 101a among the DRAM chips 101a to 101e in the MRS period after the power is turned on, so that the latch circuits LC1 to LC5 respectively latch different self-chip addresses LA having 3 bits. Different self-chip addresses are assigned to the DRAM chips 101a to 101e, respectively.

The comparator circuit 13 which compares a self-chip address LA stored in the latch circuit with a chip select address CA input from the outside in the operation of the DRAM chip after the MRS period, and outputs a chip select signal Sci having the H level when the addresses LA and CA are identical will be described.

FIG. 7 is a diagram showing the configuration of the comparator circuit 13 provided in each of the automatic chip recognition/selection circuits 900a to 900e of FIG. 2. As shown in FIG. 7, the comparator circuit 13 includes three EXNOR (exclusive NOR) circuits of an EXNOR circuit 71, an EXNOR circuit 72, and an EXNOR circuit 73, and an AND circuit 74.

By this configuration, it is possible to compare the self-chip address LA with the chip select address CA, which is common to the chips and input from the outside via the interface chip 103.

In FIG. 7, the EXNOR circuit 71 receives an address signal B0′ of the self-chip address LA and an address signal B0 of the chip select address CA. The EXNOR circuit 72 receives an address signal B1′ of the self-chip address LA and an address signal B1 of the chip select address CA. The EXNOR circuit 73 receives an address signal B2′ of the self-chip address LA and an address signal B2 of the chip select address CA. Each of the EXNOR circuits 71, 72, and 73 is a circuit which senses whether the logic levels of the two input address signals are identical or different, outputs 0 when the logic levels of the two address signals are different, and outputs 1 when the logic levels of the two address signals are identical.

The AND circuit 74 receives respective outputs of the three EXNOR circuits 71, 72, and 73, and outputs an arithmetic output thereof as a chip select signal Sc. Accordingly, if it is sensed that two inputs of all the three EXNOR circuits 71, 72, and 73 are identical, the output of the AND circuit 74 becomes 1 and the chip select signal Sc has the H level. On the other hand, if it is sensed that two inputs of any one of the three EXNOR circuits 71, 72, and 73 are different, the output of the AND circuit 74 becomes 0 and the chip select signal Sc has the L level. As described above, one DRAM chip to which a desired self-chip address LA is assigned can be selected on the basis of the chip select signal Sc.

The execution of a read or write operation of the DRAM chip 101i of FIG. 2 is allowed when a chip select signal Sci output from the comparator circuit 13 of each of the five automatic recognition/selection circuits 900a to 900e in FIG. 2 is supplied to the command decoder 130 of each DRAM chip 101i and the chip select signal Sci has the H level. An external controller can selectively operate an arbitrary DRAM chip among the stacked DRAM chips by supplying chip select addresses CA to various control commands such as a read command and a write command.

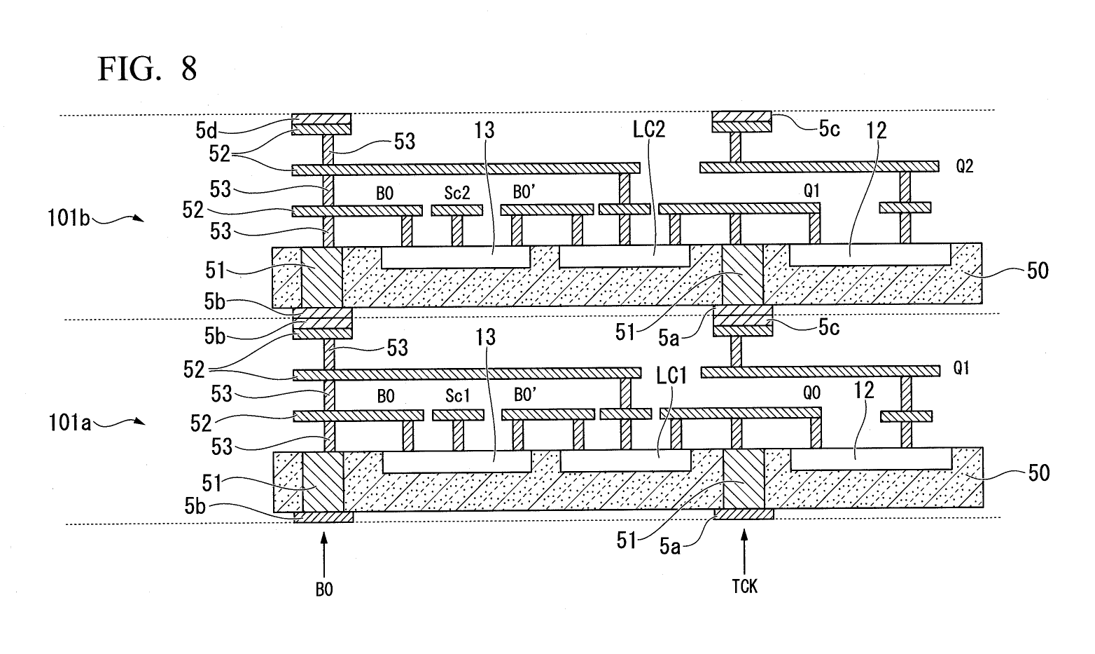

A connection structure between the DRAM chips in the stacked semiconductor device of this embodiment will be described. FIG. 8 is a diagram schematically showing a cross-sectional structure of a range including the DRAM chip 101a and the DRAM chip 101b facing each other in the stacked semiconductor device of FIG. 1. The range of the first-layer DRAM chip 101a and the second-layer DRAM chip 101b a is shown in FIG. 8, but descriptions based on FIG. 8 is common to all the DRAM chips 101a to 101e of the layers having the same structure.

As shown in FIG. 8, the DRAM chip 101a includes the above-described frequency change circuit 12 (TFF circuit), the latch circuit LC1, and the comparator circuit 13 which are formed on a semiconductor substrate 50. A bump electrode 5a and a bump electrode 5b are arranged on a lower surface of the semiconductor substrate 50, and a bump electrode 5c and a bump electrode 5d are arranged above an upper surface thereof. Connection paths for connecting the reference pulse signal TCK with the chip select address CA are formed by the DRAM chip 101a and the bump electrode 5a and by the DRAM chip 101a and the bump electrode 5b.

In the DRAM chip 101a, a through electrode 51 passing through the semiconductor substrate 50, multilayer metal wiring layers 52 above the semiconductor substrate 50, and a plurality of through holes 53 passing through insulating layers between the metal wiring layers 52 are formed. Connection paths for address signals B0 of chip select addresses CA are shown in the connection structure of FIG. 8, but connection paths for the other address signals B1 and B2 of the chip select addresses CA have a structure common to that of the address signal B0, and connection paths for the other pulse signals have a structure common to pulse signals Q0 and Q1.

For the pulse signal Q0, a connection path reaching an input side of the frequency change circuit 12 (TFF circuit) and a connection path reaching an input side of the latch circuit LC1 are formed via the bump electrode 5a, the through electrode 51, the through hole 53, and the metal wiring layer 52. To supply the pulse signal Q1 as the output of the frequency change circuit 12 to the upper-layer DRAM chip 101b, a connection path reaching the bump electrode 5a of the lower surface of the upper-layer DRAM chip 101b via the metal wiring layer 52, the through hole 53, and the bump electrode 5c is formed.

For the pulse signal Q0, a connection path reaching an input side of the latch circuit LC1 via the through hole 53 and the metal wiring layer 52 is also formed. For the address signal B0′ as the output of the latch circuit LC1, a connection path reaching the comparator circuit 13 via the through hole 53, the metal wiring layer 52, and the through hole 53 is formed.

On the other hand, for the address signal B0, a connection path reaching the bump electrode 5d of the upper surface via the bump electrode 5b of the lower surface, the through electrode 51, the through hole 53, and the metal wiring layer 52 is formed, and paths branched from the metal wiring layer 52, that is, a connection path reaching the input side of the comparator circuit 13, and a connection path reaching the input side of the latch circuit LC1, via the through hole 53, are formed. A wiring pattern for the chip select signal Sc1 output from the comparator circuit 13 is connected to an input of the command decoder 130 (not shown in FIG. 8) via the through hole 53 and the metal wiring layer 52.

As is apparent from the connection structure of FIG. 8, linear connection paths to which the stacked semiconductor device is connected in a longitudinal direction are formed for the address signals B0, B1, and B2 of the chip select address CA. On the other hand, a structure which sequentially connects the through electrodes 51, the through holes 53, the metal wiring layers 52, and the frequency change circuits 12 of the layers of the stacked semiconductor device from a low layer to an upper layer is formed for the pulse signal Qi. Connection paths for the address signals B0, B1, and B2 of the chip select address CA and the pulse signal Qi can be formed in the same structure for all DRAM chips.

If a configuration using a self-chip address of a low-layer DRAM chip is adopted when a self-chip address LA is stored, it is necessary to provide a connection path for inputting/outputting the self-chip address to/from each DRAM chip. That is, it is necessary to form connection paths of the self-chip address LA whose number is the same as that of the chip select address CA. On the other hand, since a configuration in which DRAM chips facing each other exchange the pulse signal Qi is adopted in the connection structure of this embodiment, it is not necessary to provide a connection path for inputting/outputting the self-chip address. Since only one connection path which exchanges a pulse signal Qi is provided even when the number of stacks for DRAM chips is increased and the number of address signals for chip select addresses CA is increased, a wiring structure can be simplified.

A stacked semiconductor device according to this embodiment is configured to select a desired semiconductor chip (DRAM chip 101i) by individually allocating different self-chip addresses (self-chip addresses LA) to m (m=5) stacked semiconductor chips. The semiconductor chip (DRAM chip 101i) includes a frequency change circuit (frequency change circuit 12), connected in cascade according to a stack order of the m (m=5) semiconductor chips, for dividing an input pulse (pulse signal Qi) and outputting a division signal to the next-stage semiconductor chip. The semiconductor chip (DRAM chip 101i) includes a self address storage circuit (latch circuit LCi) for receiving a chip select signal (chip select address CA) commonly supplied to the m semiconductor chips in a time when a logic level of an input division signal is different from logic levels of division signals input to the other (m-1) frequency change circuits (frequency change circuits 12) to store as a self-chip address (self-chip address LA). The semiconductor chip (DRAM chip 101i) includes a determination circuit (comparator circuit 13) for comparing the chip select address (chip select address CA) with the self-chip address (self-chip address LA) and determining whether the chip select address and the self-chip address are identical.

According to the stacked semiconductor device of the embodiment of the present invention, since the latch circuit LCi of the automatic chip recognition/selection circuit 900i is configured to store the self-chip address LA in a mode register setting period (MRS period) after the power is turned on after stacking, a process of recognizing the self-chip address LA is unnecessary in a step of the semiconductor chip (DRAM chip 101i), so that there is an advantageous effect in that an increase in manufacturing cost is suppressed. Also, since a program process before the stacked semiconductor device is manufactured is unnecessary, there is an advantageous effect in that an increase in manufacturing cost is suppressed.

Since the frequency change circuit 12 outputs a signal whose cycle is changed to a multiple to an upper-layer semiconductor chip, it is preferable that the number of connection paths be 1. That is, it is not necessary to provide n connection paths for a self-chip address between semiconductor chips stacked for an input/output of an arithmetic circuit as in a stacked semiconductor device in which an arithmetic circuit which generates an n-bit self-chip address is provided in an individual semiconductor chip, so as to compare the self-chip address with an n-bit chip select address supplied from the outside. Since the number of connection paths can be reduced from n to 1, there is an advantageous effect in that an increase in chip area can be suppressed. Also, since the occurrence of a conduction failure due to an assembly failure can be suppressed, manufacturing yield can be improved, and manufacturing cost can be reduced.

Although the invention made by the present inventors has been described with reference to the embodiments, the present invention is not limited to the above-described embodiments and various modifications can, of course, be made without departing from the spirit and scope of the present invention. For example, a stacked semiconductor device in which DRAM chips are stacked in five layers in this embodiment has been described, but the present invention may also be applied to the case where a larger number of chips or a smaller number of chips are stacked.

A stacked semiconductor device in which a plurality of DRAM chips are stacked has been described in this embodiment, but the present invention may be widely applied to stacked semiconductor devices in which various semiconductor chips other than DRAM chips are stacked. The embodiments of the present invention is not limited to semiconductor memory chips like DRAM chips, and may be widely applied to general semiconductor devices in which various semiconductor chips are stacked.

Since a range of 0 to 7 can be expressed by a 3-bit self-chip address LA in a configuration example of the embodiment, the maximum number of DRAM chips capable of being stacked becomes 8. However, if a larger number of DRAM chips are stacked, it is necessary to increase the number of bits of a corresponding chip select address CA and configure the latch circuit and the comparator circuit 13 corresponding to a number of bits.

For example, since a self-chip address LA has n bits if a chip select address CA is a combination of n bits, the latch circuit is configured to store the n-bit self-chip address LA. The comparator circuit 13 is configured to compare the n-bit self-chip address LA with the n-bit chip select address CA and generate a chip select signal Sci if the addresses LA and CA are identical. By these configurations, it is possible to freely set the number of DRAM chip stacks, m, in the range of 2ⁿ⁻¹<m≦2ⁿ. Even when the number of bits of the chip select address CA is increased to n, it is sufficient that the number of connection paths of a pulse signal Qi is 1 in the stacked semiconductor device as described above and it is not necessary to form an additional connection path.

The embodiments of methods, software, firmware or codes described above may be implemented by instructions or codes stored on a machine-accessible or machine readable medium. The instructions or codes are executable by a processing element or processing unit. The machine-accessible/readable medium may include, but is not limited to, any mechanisms that provide, store and/or transmit information in a form readable by a machine, such as a computer or electronic system. In some cases, the machine-accessible/readable medium may include, but is not limited to, random-access memories (RAMs), such as static RAM (SRAM) or dynamic RAM (DRAM), read-only memory (ROM), magnetic or optical storage medium and flash memory devices. In other cases, the machine-accessible/readable medium may include, but is not limited to, any mechanism that receives, copies, stores, transmits, or otherwise manipulates electrical, optical, acoustical or other form of propagated signals such as carrier waves, infrared signals, digital signals, including the embodiments of methods, software, firmware or code set forth above.

Furthermore, the particular features, structures, or characteristics may be combined in any suitable manner in one or more embodiments.

It is apparent that the present invention is not limited to the above embodiments, but may be modified and changed without departing from the scope and spirit of the invention.

What is claimed is:

1. A semiconductor device comprising:
a plurality of stacked chips which are allocated with different self-chip addresses,
each of the plurality of stacked chips comprising:
a frequency change circuit that changes a first frequency of a signal into a second frequency of the signal;
a self-address storing circuit that stores a chip select address that is supplied to other chips, in a period of time when the signal as input to the frequency change circuit is different in logic level from the signals as input to the frequency change circuits in the other chips; and
a determination circuit that determines whether the chip select address is identical to the self-chip address.

2. The semiconductor device according to claim 1, wherein the second frequency is two times as high as the first frequency.

3. The semiconductor device according to claim 1, wherein the signal is a digital signal, and the frequency change circuit comprises a frequency divider that frequency-divides the signal to generate a frequency-divided signal.

4. The semiconductor device according to claim 3, wherein the frequency change circuits of the plurality of stacked chips are connected in series and the frequency divider supplies the frequency-divided signal to a next stage frequency divider on the next stage.

5. The semiconductor device according to claim 4, wherein the chip select address is represented by a combination of n-bits, satisfying 2ⁿ⁻¹<m≦2ⁿ, where m is the number of the stacked chips.

6. The semiconductor device according to claim 5, wherein each of the plurality of stacked chips further comprises n of connection path that commonly connects the stacked chips where n is an integer greater than 1, and a single connection path that connects in series the frequency change circuits of the stacked chips.

7. The semiconductor device according to claim 6, wherein n of the connection path and the single connection path are common in structure to the plurality of stacked chips.

8. The semiconductor device according to claim 1, wherein the frequency change circuit comprises a toggle flip-flop.

9. The semiconductor device according to claim 1, wherein the signal input into the frequency change circuit of the chip on a first stage is an external periodic pulse supplied from outside the semiconductor device.

10. The semiconductor device according to claim 1, wherein in the period of time the determination circuit in the each chip generates a self-chip select signal that selects the each chip and allows an access to the each chip, when the determination circuit determines that the chip select address is identical to the self-chip address.

11. The semiconductor device according to claim 1, wherein the period of time comprises a mode register setting time period.

12. The semiconductor device according to claim 1, wherein in a normal operation period the determination circuit in the each chip generates a self-chip select signal that selects the each chip and allows an access to the each chip, according to address signals that are supplied from outside the semiconductor device.

13. The semiconductor device according to claim 12, wherein each of the stacked chips is a DRAM chip.

14. The semiconductor device according to claim 13, wherein each of the stacked chips comprises a command decoder, and in the normal operation period the determination circuit in the each chip supplies the self-chip select signal to the command decoder in the each chip.

15. A semiconductor device comprising:
a frequency change circuit that changes a first frequency of a signal, which is input, into a second frequency of the signal;
a self-address storing circuit that stores a chip select address, a mode register setting time period; and
a determination circuit that determines whether the chip select address is identical to a self-chip address that is allocated to a chip, the chip comprising the frequency change circuit, the self-address storing circuit, and the self-address storing circuit.

16. The semiconductor device according to claim 15, wherein in the mode register setting time period the determination circuit generates a chip select signal, when the determination circuit determines that the chip select address is identical to the self-chip address.

17. The semiconductor device according to claim 15, wherein in a normal operation period the determination circuit generates a self-chip select signal, according to address signals that are supplied from outside the semiconductor device.

18. The semiconductor device according to claim 15, wherein the frequency change circuit, the self-address storing circuit, and the determination circuit are integrated in a DRAM chip stacked with at least one other chip.

19. A semiconductor device comprising:
a plurality of stacked chips which are allocated with different self-chip addresses, each of the plurality of stacked chips comprising:
a memory cell array; and
a peripheral circuit coupled to the memory cell array, the peripheral circuit comprising:
a frequency change circuit that changes a first frequency of a signal into a second frequency of the signal;
a self-address storing circuit that stores a chip select address that is supplied to other chips, in a period of time when the signal as input to the frequency change circuit is different in logic level from the signals as input to the frequency change circuits in the other chips; and
a determination circuit that determines whether the chip select address is identical to the self-chip address.

20. The semiconductor device according to claim 19, wherein the chip select address is represented by a combination of n-bits, satisfying 2ⁿ⁻¹<m≦2ⁿ, where m is the number of the stacked chips, and
wherein each of the plurality of stacked chips further comprises n of connection path that commonly connects the stacked chips where n is an integer greater than 1, and a single connection path that connects in series the frequency change circuits of the stacked chips.
